(19) United States
(12) Patent Application Publication
(10) Pub. No.: US 2008/0238245 A1
(43) Pub. Date: Oct. 2, 2008

(54) Piezoelectric switch with symbolic illumination

(75) Inventors: Yaacov Ozer, Wan Chai (HK); Josef Winner, Kowloon (HK)

Correspondence Address: Martin D. Moynihan;PRTSI, Inc., P.O. Box 16446, Arlington, VA, 22215, US

(73) Assignee: Rosslare Enterprises Ltd., Kowloon Bay (HK)

(21) Appl. No.: 11/727,718

(22) Filed: Mar. 28, 2007

(51) Int. Cl. H01L 41/113

(52) U.S. Cl. 310/314; 310/319

(57) ABSTRACT

An element for an illuminated piezoelectric switch, comprises a substantially lens-like body having a first major surface and a second major surface, an illumination input at the first major surface, and a protrusion extending from the second major surface. The protrusion is integral to the construction of the lens. When the element is placed between a piezoelectric crystal and a pressing surface it transmits pressure to the crystal in one direction, and in the other direction it transmits light from a lighting element below, towards the protrusion. The protrusion is shaped so that the switch can be identified.

### FIELD AND BACKGROUND OF THE INVENTION

The present invention relates to a piezoelectric switch with symbolic illumination and to devices incorporating such switches. More particularly but not exclusively the invention relates to the field of piezoelectric human interface elements for electronic, electrical, mechanical or electromechanical equipment, in which the interface elements include a clear indication of the purpose of the element, and or distinguish a given interface element from other elements on the same device, and which interfaces can be lit for viewing in bad lighting conditions.

Existing piezoelectric human interface commanding elements include the following items:

(1) Piezoelectric switches which are printed with relevant symbols on their external contact surface, without illumination. These are difficult to use in the dark.

(2) Piezoelectric switches with a light-pipe guide, where the external contact interface of the switch is a mechanical light-pipe element. The switch includes printed symbols on the surface which are backlit through the light pipe.

(3) Piezoelectric switches with a light-ring or other illuminated boundary, based on a mechanical light-guide element which surrounds the switch area. Again a backlighting effect can be achieved but because the ring is external the effect within the switch itself is weaker.

(4) Switches that are lit using an external illumination source. The external source lights the switch area, say from above or from the side, and the switches themselves are printed with relevant symbols on their external contact surface.

U.S. Pat. No. 5,770,914 teaches an illuminated piezoelectric switch. The patent deals with a piezoelectric switch based on a flexible piezoelectric film substrate which may carry the electronic components. The press sensing area includes a hole for an LED light to pass through the piezoelectric crystal, which is thereby weakened.

U.S. Pat. No. 5,142,183 teaches an electronic switch assembly. A structure and a production method is taught for the switch in order to avoid an accurate and expensive shaping of the piezoelectric element. The teaching includes an option for a light-ring for lighting purposes.

U.S. Pat. No. 5,636,729 teaches a piezoelectric switch with a lit push button. Based on a shaped light pipe, a transparent part creates the external contact area and delivers the pressure to a piezoelectric ring shaped element below it. The light is generated by an LED located below the piezoelectric element and passes through the ring hole, through the transparent material to the surface.

Piezoelectric switches are commonly used with equipment working in harsh environments, where the controlled device or the human interface is subject to damages, vandalism and accidental activation. The Piezoelectric switch is suitable for such environment being rigid, metallic and having no moving parts.

As with any commanding or interfacing elements, piezoelectric switches require a means that describes their function to the user. In most cases such a means is a printed label, placed on the metallic surface of the switch or in the vicinity of the switch. Since piezoelectric switches usually operate either in harsh environments or in unprotected areas and may be used frequently by different operators. Consequently the labels may be erased, fade or become blurry over time. Furthermore, printed labels are not useful in dark or dimmed light conditions, and such conditions are commonly encountered in piezoelectric switches located in the kind of devices which are located outdoors or in areas which are not lit at night, currently requiring such areas to be especially lit for the purpose of using the device.

Piezoelectric switches with an illuminated light-pipe may have a printed label over the external surface of the light-pipe to be back lit via the light pipe and thereby to show the switch functionality even in the dark. However, the printed label may be erased, torn, fade or blur over time. The light-pipe must be made of a transparent material, and a plastic material is typically used. Being the external contact area of the switch, and not being as rigid as the switch metallic surface, the material may be damaged easily, causing the switch to stop functioning. Furthermore, a printed label over a lit background creates a dark image over an illuminated surface, which is hard to identify.

Piezoelectric switches with a light-ring or an illuminated boundary are also common however they do not contribute to the purpose of easy identification of the switch function, only showing its location.

An external light source that lights the switch area is a known solution. However, on many devices the light source is necessarily located near to the plane of the switches. Thus the illumination comes from a narrow angle relative to the surface and does not effectively illuminate the switches. Furthermore the light source can easily be damaged or blocked. Also the solution makes the device cumbersome and disrupts the product design.

A solution is required to satisfy the need for a piezoelectric switch with symbolic labeling suitable for location in a harsh environment, including dark or low light locations. The solution should be suitable for frequent use by different operators, and should be sufficiently rugged as to allow exposure to a harsh treatment, vandalism and accidental activation. The solution should retain its lighting strength at a reasonable level over time, and also retain a reasonable level of sensitivity and accuracy of the press area. The production method should be practical and should be achieved with usage of standard materials and conventional production technology and means, without the need to create accurate and expensive shaping of the piezoelectric or other elements, without disrupting the piezoelectric element sensitivity by significant shape modifications and without dedicated tuning or trimming tasks.

There is thus a widely recognized need for, and it would be highly advantageous to have, a device that is devoid of the above limitations and fulfils the above need.

### SUMMARY OF THE INVENTION

According to one aspect of the present invention there is provided an element for a piezoelectric switch, comprising:

a substantially lens-like body having a first major surface and a second major surface,

at least one illumination input at said first major surface for insertion of light into said lens like body, and

a protrusion extending from said second major surface, said protrusion comprising an extension of a material of said lens body, the shape of the body thereby providing a light path from said illumination input to said protrusion.

According to a second aspect of the present invention there is provided a piezoelectric switch comprising:

a piezoelectric crystal,

a pressing surface, and

an element located between said switching surface and said body, said element comprising:

a substantially lens-like body having a first major surface towards said piezoelectric crystal, and a second major surface towards said pressing surface,

at least one illumination input at said first major surface, and

a protrusion extending from said second major surface through said switching surface, said protrusion comprising an extension of a material of said lens body, the lens like body defining a light path such that light entering at said at least one illumination input is channeled into said extending symbol.

Preferably, the second major surface is substantially entirely in contact with said pressing surface and said first major surface is substantially in contact with an entirety of an upper surface of said piezoelectric crystal, thereby to provide homogenous transmission of pressing energy from said pressing surface to said crystal.

Unless otherwise defined, all technical and scientific terms used herein have the same meaning as commonly understood by one of ordinary skill in the art to which this invention belongs. The materials, methods, and examples provided herein are illustrative only and not intended to be limiting.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in order to provide what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 is a simplified diagram illustrating a lens element according to a first preferred embodiment of the present invention.

FIG. 2 is a view from below of the element of FIG. 1.

FIG. 3 is a cross section of a piezoelectric switch according to a preferred embodiment of the present invention incorporating the element of FIG. 1.

FIG. 4 is a simplified exploded diagram of a device incorporating a piezoelectric switch according to a preferred embodiment of the present invention.

FIG. 5 is a cross-section of a device incorporating several piezoelectric switches according to a preferred embodiment of the present invention.

FIG. 6 is an exploded diagram of the device in FIG. 5.

### DESCRIPTION OF THE PREFERRED EMBODIMENTS

The present embodiments comprise an apparatus and a method for a piezoelectric switch which includes an illuminated symbolic shape on its metallic surface. The symbolic shape is an outgrowth or extrusion of a lens body which extends from an initial light guide input. The light guide input is peripheral to the structure of the lens but the symbolic shape is central to the piezoelectric switch so that light is guided around and over the piezoelectric crystal which is the base of the switch, in such a way that no interference to the piezoelectric crystal is needed to feed the light, and yet the switch is centrally illuminated. Furthermore there is no need for printed symbols on the switch.

The lens also serves as the mechanical transmitter of pressure to the crystal so that the illuminated switch provides good and homogenous sensitivity with an accurate press area and keeps reasonable strength. The majority of the press area remains metallic, and as the mechanical signal is delivered directly to the piezoelectric element, the switch remains functioning even in the case of damage to the shape form.

As will be explained below in more detail, the present embodiments provide a method of switch design under common production methods which does not significantly disrupt the shape of the piezoelectric element nor its symmetrical form which is important to keep its sensitivity homogenous over its surface. The method combines a dedicated design of the lens so as to serve both as the light pipe and for delivery of the mechanical signal to the piezoelectric crystal element. What is described below is a structure which keeps most of the strength of the external metallic contact surface. A high level of accuracy of the press area is provided due to the design of the metallic surface which houses the piezoelectric crystal element and the lens which fits into dedicated receptacle locations or sockets inside the housing.

As will be explained in greater detail below, the metallic surface has a shaped opening for the illuminated symbol, and the metallic surface and shaped transparent lens are made of standard materials and are manufactured with standard, inexpensive and common injection-molding and CNC machining technologies.

The principles and operation of an apparatus and method according to the present invention may be better understood with reference to the drawings and accompanying description.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

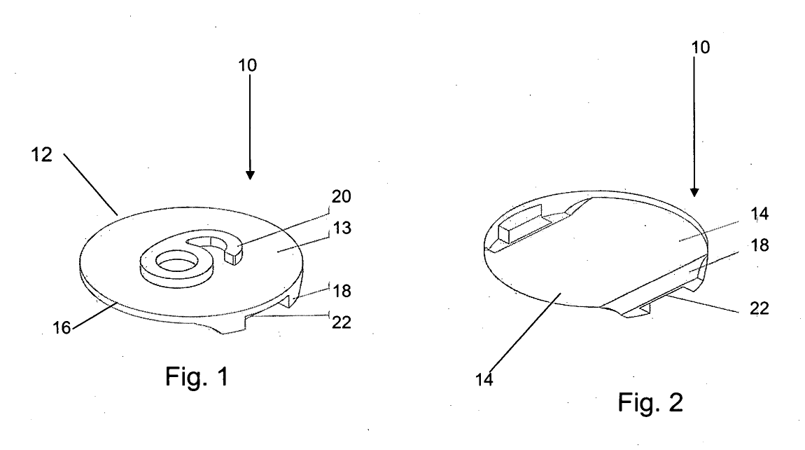

Reference is now made to FIG. 1, which illustrates an element for a piezoelectric switch. The element 10 comprises a substantially lens-like body 12 with upper 13 and lower 14 surfaces—the major surfaces as distinct from the minor circumferential surface 16 in the plane of the lens. The element 10 further includes one and preferably two illumination inputs 18, essentially light guides to guide light into the body 12 of the lens. The illumination inputs 18 are preferably formed into the lower surface 14, and a protrusion 20 extends from the upper surface. The protrusion is preferably an extension of the material of the lens body.

The light guides 18 are smoothly rounded at their edges, and the edges are relatively long. A light guide surface is created which is substantially perpendicular to the upper surface 13 of the lens body 12, so that light that enters the light guides is broadly scattered towards the central region of the upper lens and towards protrusion 20. The light guides include extruded cuts 22 for fitting over light emitting diodes or any other suitable light source, so that the light sources emit light directly into the light guides.

As shown in FIG. 1, protrusion 20, centrally located on upper surface 13, is preferably in the form of a symbol, and the symbol is chosen to indicate the function of the button.

Preferably the illumination inputs 18 are located substantially peripherally around surface 14. The reason is to allow surface 14 to sit over a piezoelectric crystal. The edges of the crystal may be cut to accommodate the light guides but with the present arrangement the light feeding mechanism does not interfere with the crystal itself, and does not reduce either its electrical efficiency or its mechanical properties.

Lens-like body 12 is preferably formed from a substantially transparent plastic or glass material, although dye substances may be added. Using a dye would have the effect of coloring the light output but more importantly makes the symbols more distinctive, including during daylight. If made from a plastics material then the lens-like body may be substantially molded to integrate the protrusion and light guides. Cutting may be used to sharpen the results of molding.

FIG. 2 is a simplified diagram showing element 10 of FIG. 1 on its reverse side 14. The lower surface of light guides 18 are shown as well as the lower surface of protrusions 22 for fitting over LEDs.

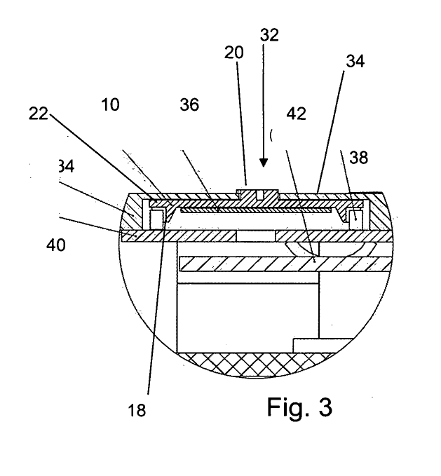

Reference is now made to FIG. 3, which is a simplified cross-sectional diagram of a piezoelectric switch 30 comprising an element 10. Element 10 is located between a pressing surface 34 and a piezoelectric crystal 36 and is able to transmit pressing force from the pressing surface to the piezoelectric element. That is to say it is shaped to ensure mechanical pressure on the pressing surface is efficiently transmitted to the piezoelectric crystal 36. Lighting elements 38, typically light emitting diodes, LEDs, lie under the wings of element 10 away from the piezoelectric crystal 36 and it can clearly be seen from the cross section how the LEDs fit into the undersurface defined between the light guide legs 18 and the cut out protrusions 22.

As the LEDs are lit, light is directed by the shaping of the light-guide lens structure, from the LEDs, around and over the piezoelectric crystal and towards protrusion 20. Secondary PCBs 40 and 42 support and power the LEDs.

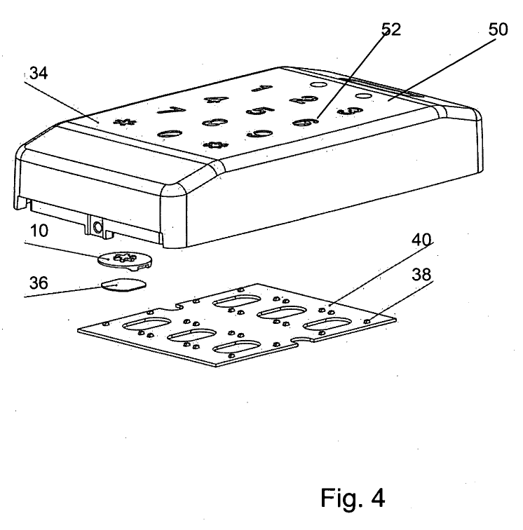

Reference is now made to FIG. 4, which is a simplified exploded diagram illustrating how the parts of a single switch fit together. Parts referred to in previous diagrams are given the same reference numerals. Upper pressing surface 34 is part of a casing 50 having cut-out shapes 52 to correspond with the protrusions of the individual switches. Typically casing 50 and pressing surface 34 are metallic.

Element 10 is placed under the pressing surface with protrusion 20 inserted into cut-out shape 50. Piezoelectric crystal 36 locates underneath element 10, such that upon pressing of upper pressing surface 34, mechanical transmission occurs through element 10 to crystal 36 to compress crystal 36 and cause it to produce a voltage. PCB board 40 supports lighting elements 38 which in turn fit under elements 10 outside of crystals 36.

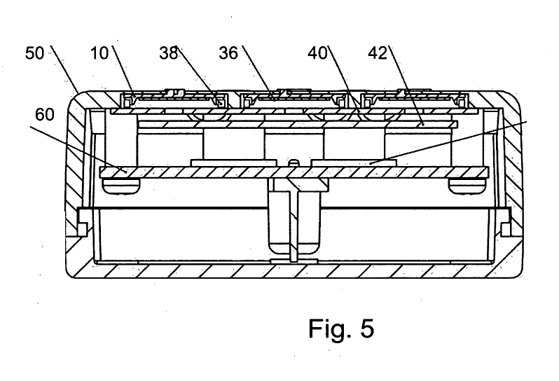

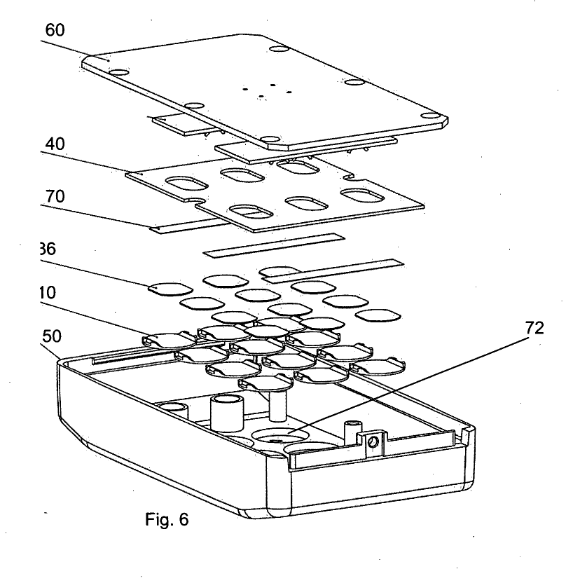

Reference is now made to FIG. 5, which is a simplified cross section showing three piezoelectric switches of the above embodiments shown side by side, as would be typical in a row of a numeric keypad. The switches are located on a main PCB 60 and each switch has the structure of above FIG. 3. The switches are based on a regular piezoelectric crystal element 36 as discussed and a metallic pressing surface 34 which provides the external contact area for activation of the switch. The metallic surface contains shaped openings 52 as discussed above with respect to FIG. 4, and which are in the shapes of the protrusions 20. As mentioned the protrusions 20 are shaped into numbers, letters or other symbols which describe the switch function. The shaped lens element 10 of FIG. 1 is made of transparent material. The lens element 10 has an external shape that fits into a designated press area under surface 34 where the thickness of surface 34 is reduced to accommodate and clearly locate the lens, a sort of socket—see FIG. 6 part no. 72. Location of the lens within a shaped socket allows for a very high accuracy of mechanical transmission in the press area. The lens-like body 10 is protected by the metal surface 34 over most of its area, thus keeping the structural strength of the switch mechanism at a reasonable level. The lens-like body 10 preferably has a base which is relatively large comparing to its shaped portion and is accurately located below the press area as explained to retain good and homogenous sensitivity, in the sense that pressure applied to the press area may be equally transferred to the crystal whether the pressure is centrally applied on the press area or not.

A press is delivered by a user from the metal surface 34 through the lens 10 to the piezoelectric crystal element 36 which generates an electrical signal. The signal is delivered to the main PCB 42 which includes electronic circuitry for translating and delivering the switch signals to any required control application.

As explained in respect of FIG. 1, the lens element 10 has a dedicated shape, both of the light guides 18, body 12 and of the protrusion 20. The shape is responsible for creation of the symbol, bringing the light properly to the surface of the symbol and for delivery of the press homogenously and effectively to the piezoelectric crystal element 36.

The secondary PCBs 40 and 42 serve among other functions to hold the LED indicator 38, welded in SMT (surface mount technology). The secondary PCBs are located above main PCB 60, closer to the switches. As explained there are two LED indicators 38 located under the edges of each switch. The shape of the lens 10 is designed to redirect and to deliver the light to the shaped surface. This is achieved by a dedicated design of the lens. The lens 10 is based on a thin rounded surface 13 comprising shaped protrusion 20 which forms the symbol, and two straight protrusion areas 18 on its lower side 14 which behaves as light guides. The light guides 18 include extruded cuts 22 in them which fit the LED indicators 38 in their location on the secondary PCB 40.

When the LED indicators 38 are lit, light is redirected by the lens light guide geometry to the rounded surface 13. More particularly the shape of the light guides is smoothly rounded on edges which are relatively long, and the light guide surface forms an area which is perpendicular to the surface 13. The result is to generate a smooth and homogenous light scattering toward the center area of the surface 13 without significant losses at the area below it. The light, which is focused in the central area of the surface 13 is then efficiently delivered to the shaped form 20.

The piezoelectric crystal element 36 is preferably made of a thin rounded surface with cut edges. These cuts ensure room for light delivery using the lens light guides 18. Compared to older methods such as drilling in the center of the piezoelectric element, the present method is simpler for mass production and does not significantly disrupt the homogenous sensitivity of the piezoelectric crystal as would happen with drilling its center.

Foam bars 70 may be attached to the secondary PCB in order to increase light blocking to avoid light leaking or dripping from one lens to another. Such is useful in the case of multiple switch arrangements where different switches are lit while others remain unlit. Generally in a numeric keyboard all the switches are lit together, and the keyboard is used as a whole, but this may not always be the case.

The effect of achieving a homogeneous pressing sensitivity depends very much on the effectiveness of pressure delivery from the metal surface 34 to the piezoelectric crystal element 36. The piezoelectric crystal element 36 achieves best performance when it moves from zero to maximum deformation at any application of pressure on the metallic surface 34. Thus the entire transmission system is preferably provided with a homogenous and symmetric shape in order to increase the effectiveness of the delivery of the mechanical signal to its surface. Delivery may depend in particular on the straightness of the lower surface 14 of the lens element 10 which is the surface in contact with the piezoelectric crystal element 36. Best delivery is when surface 14 is in direct contact with the crystal, and combinations with other materials or layers may disrupt the effectiveness and the homogeneity of the mechanical signal delivered to the piezoelectric element.

As discussed above, lens element 10 is preferably made of a clear and not pigmented transparent, preferably of plastic. A colored effect may then be achieved by painting the lower surface 14 with a required color. Such an arrangement keeps the backlit color strong, but the color should be chosen in accordance with the color of the LED indicators. Coloring of the lower surface of the lens has the effect of filtering the required light color while keeping the intensity high overall. The alternative, as mentioned above is to have a low concentration of pigment throughout the lens element.

Reference is now made to FIG. 6, which is an exploded diagram that extrapolates the construction of a single piezoelectric switch to multiple switches of a numeric keypad. Parts discussed in earlier figures are given the same reference numerals and are not discussed again, except as necessary for an understanding of the present figure. The shaped upper protrusion 20 of lens element 10 is inserted into an opening 52 of housing 50. The rounded upper surface 13 of element 10 fits into socket 72 to define a pressing area of housing 50. Thus a press made by a user is exerted mainly on the metal surface and is delivered directly to the relatively homogenous rounded upper surface 13. The rounded upper surface is preferably secured in the socket 72 using a strong adhesive which is non-water based so as to keep the device as a whole waterproof. The mechanical signal is then delivered directly to the piezoelectric crystal element 36 which is of rounded plate form and directly attached to the bottom side 14 of the lens element 10, likewise using strong adhesive. A structure based on flat surfaces which are attached one to each other over most or all of their areas—metallic surface 50 to the lens element 10, the lens element 10 to the piezoelectric crystal element 36—provides an efficient and homogenous delivery of the mechanical signal. Since the signal arriving at the piezoelectric crystal element is homogenous, there is no need to increase sensitivity to compensate for low signal areas. Current systems which include such compensation risk over sensitivity in the high signal areas, and this difficulty is thereby obviated. An overall sensitivity may be set for the device that may be shared by multiple switches sharing the metallic surface.

The necessary accuracy of the inner metal surface, which is important for the effectiveness of the pressure delivery to the piezoelectric element is achieved by CNC machining, which also provides accurate location of the piezoelectric crystal element 36 below the press area and the lens element 10.

The accuracy of the openings 52 in the metal surface 50 is sufficient to allow the lens protrusion 20 to fit tightly in the opening, but preferably is not so tight as to apply force by itself. Rather the majority of the force is preferably delivered by the rounded surface 13 of the lens element 10 to the piezoelectric crystal element (4). To achieve such a tightness accuracy, the surface may be etched and laser recessed.

It is expected that during the life of this patent many relevant devices and systems will be developed and the scope of the terms herein, is intended to include all such new technologies a priori.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents, and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

What is claimed is:

1. An element for a piezoelectric switch, comprising:
a substantially lens-like body having a first major surface and a second major surface,
at least one illumination input at said first major surface for insertion of light into said lens like body, and
a protrusion extending from said second major surface, said protrusion comprising an extension of a material of said lens body, the shape of the body thereby providing a light path from said illumination input to said protrusion.

2. The element of claim 1, wherein said protrusion forms a symbol.

3. The element of claim 1, wherein said illumination input is located substantially peripherally to said first major surface.

4. The element of claim 2, wherein said symbol extending is located substantially centrally to said second major surface.

5. The element of claim 1, wherein said illumination input is located substantially peripherally to said first major surface, said protrusion is located substantially centrally to said second major surface, said light path thereby channeling light from the periphery of the first major surface to the center of the second major surface, the light being channeled therefrom into said protrusion.

6. The element of claim 1, wherein said substantially lens-like body is substantially transparent.

7. The element of claim 1, wherein said substantially lens-like body comprises a predetermined quantity of dye.

8. The element of claim 1, wherein said substantially lens like body is configured to be located between a pressing surface and a piezoelectric element and to transmit pressing force from said pressing surface to said piezoelectric element.

9. A piezoelectric switch comprising:
a piezoelectric crystal,
a pressing surface, and
an element located between said switching surface and said body, said element comprising:
a substantially lens-like body having a first major surface towards said piezoelectric crystal, and a second major surface towards said pressing surface,
at least one illumination input at said first major surface, and
a protrusion extending from said second major surface through said switching surface, said protrusion comprising an extension of a material of said lens body, the lens like body defining a light path such that light entering at said at least one illumination input is channeled into said extending symbol.

10. The piezoelectric switch of claim 9, wherein said pressing surface comprises an opening shaped for said protrusion to extend therethrough.

11. The piezoelectric switch of claim 10, wherein said protrusion is formed as a symbol.

12. The piezoelectric switch of claim 11, wherein said opening is formed to correspond to said symbol.

13. The piezoelectric switch of claim 9, wherein said pressing surface is metallic.

14. The piezoelectric switch of claim 9, wherein said illumination input is located substantially peripherally to said first major surface.

15. The piezoelectric switch of claim 11, wherein said symbol is located substantially centrally to said second major surface.

16. The piezoelectric switch of claim 9, wherein said illumination input is located substantially peripherally to said first major surface, said protrusion is located substantially centrally to said second major surface, and said lens-like body is configured to function as a light guide to channel light from said illumination input to said protrusion.

17. The piezoelectric switch of claim 9, wherein said substantially lens-like body is substantially transparent.

18. The piezoelectric switch of claim 9, wherein said substantially lens-like body comprises a predetermined quantity of dye.

19. The piezoelectric switch of claim 9, wherein said substantially lens like body is firmly located between said pressing surface and said piezoelectric crystal such as to transmit pressing force evenly from said pressing surface to said piezoelectric element.

20. The piezoelectric switch of claim 9, wherein said element comprises an integral moulding of transparent material.

21. The piezoelectric switch of claim 19, wherein said second major surface is substantially entirely in contact with said pressing surface and said first major surface is substantially in contact with an entirety of an upper surface of said piezoelectric crystal, thereby to provide homogenous transmission of pressing energy from said pressing surface to said crystal.
